(19) United States
(12) Patent Application Publication
(10) Pub. No.: US 2019/0345326 A1
(43) Pub. Date: Nov. 14, 2019

(54) LOW-LOSS INSULATING RESIN COMPOSITION AND INSULATING FILM USING THE SAME

(71) Applicant: SAMSUNG ELECTRONICS CO., LTD., Suwon-si (KR)

(72) Inventors: Ki-Seok KIM, Suwon-si (KR); Ji-eun WOO, Suwon-si (KR); Ji-Hye SHIM, Suwon-si (KR); Hyung-Mi JUNG, Suwon-si (KR)

(73) Assignee: SAMSUNG ELECTRONICS CO., LTD., Suwon-si (KR)

(21) Appl. No.: 16/392,858

(22) Filed: Apr. 24, 2019

(30) Foreign Application Priority Data
May 11, 2018 (KR) 10-2018-0054420
Aug. 3, 2018 (KR) 10-2018-0090960

(51) Int. Cl. C08L 63/04; C08G 59/30; C08G 59/40; C08L 27/12; C08G 59/28; C08K 5/00; C08K 3/013; C08K 3/36; C08K 9/06; C08K 5/3432; H05K 1/03; C08L 61/04

(52) U.S. Cl. CPC C08L 63/04; C08G 59/308; C08G 59/4007; C08L 27/12; C08G 59/28; C08K 5/0025; C08L 2205/035; C08K 3/36; C08K 9/06; C08K 5/3432; H05K 1/0373; C08L 61/04; C08L 2203/206; C08K 3/013

(57) ABSTRACT

A low-loss insulating resin composition and an insulating film using the same are provided. The low-loss insulating resin composition comprises an epoxy resin composite including 40 to 60 parts by weight of a cyanate ester resin, 15 to 35 parts by weight of a biphenylaralkyl novolac resin, and 15 to 35 parts by weight of a fluorine-containing epoxy resin; a hardener; a thermoplastic resin; a hardening accelerator; an inorganic filler; a viscosity enhancer; and an additive.

### CROSS-REFERENCE TO RELATED APPLICATIONS

This application claims the benefit under 35 USC § 119(a) of Korean Patent Application No. 10-2018-0054420 filed on May 11, 2018 and Korean Patent Application No. 10-2018-0090960 filed on Aug. 3, 2018, in the Korean Intellectual Property Office, the entire disclosures of which are incorporated herein by reference for all purposes.

### BACKGROUND

### 1. Field

This application relates to a low-loss insulating resin composition and an insulating film using the same.

### 2. Description of Related Art

There is a demand for highly densely integrating electronic components to be implemented in a small area of a printed circuit board, on which electronic components are mounted, and a panel-level package module using a board process in response to the development of lighter, thinner, and smaller electronic components.

Accordingly, a high-performance material for a multilayer printed wiring board as well as a package including the same is also needed. Furthermore, with the advance of 5G technology, there is a growing need for low-loss insulating materials and molding materials as well as design changes in substrates and packages to minimize the loss of high frequency signals.

In order to transmit signals at high speed, it is essential to use a material having a small dielectric constant. To minimize transmission signal loss, a material having a low dielectric dissipation factor should be used.

Generally, molding materials for packages are mainly a granule type or a liquid type. In order to use such molding materials, expensive compression molding equipment may be needed and the processing time may be prolonged. Thus, there is a need for developing film-typed molding materials such as insulating materials for printed circuits in order to overcome these disadvantages. When the film-typed molding material is used as a molding material for packages, it is possible to utilize relatively cheap vacuum lamination equipment and further to reduce the processing time since a molding process and a hardening process can be separated.

With the development of high-speed wireless communication technology, a communication method using a high frequency has received attention. In a high frequency antenna package on which high frequency circuits operating in a high frequency band such as a microwave band or a millimeter wave band are mounted, signal loss should be minimized in the signal processing, and at the same time, excellent stability and reliability are required.

### SUMMARY

This Summary is provided to introduce a selection of concepts in a simplified form that are further described below in the Detailed Description. This Summary is not intended to identify key features or essential features of the claimed subject matter, nor is the Summary intended to be used as an aid in determining the scope of the claimed subject matter.

In a general aspect, a low-loss insulating resin composition includes an epoxy resin composite comprising a cyanate ester resin, a biphenylaralkyl novolac resin, and a fluorine-containing epoxy resin, an active ester hardener, a thermoplastic resin, a hardening accelerator, an inorganic filler, and a viscosity enhancer.

The epoxy resin composite may include 40 to 60 parts by weight of the cyanate ester resin, 15 to 35 parts by weight of the biphenylaralkyl novolac epoxy resin, and 15 to 35 parts by weight of the fluorine-containing epoxy resin.

The hardener may be contained in an amount of 0.5 to 1.5 equivalents based on a mixed equivalent of the epoxy resin composite.

The thermoplastic resin may be contained in an amount of 5 to 15 parts by weight based on 100 parts by weight of the epoxy resin composite and the active ester hardener.

The thermoplastic resin may be at least one selected from a polyvinyl acetal resin, a phenoxy resin, a polyimide resin, a polyamideimide resin, a polyetherimide resin, a polysulfone resin, a polyethersulfone resin, a polyphenylene ether resin, a polycarbonate resin, a polyetheretherketone resin, a polyester resin, a phenolic resin, a fluorine-based thermoplastic resin, and a polyacetal resin.

The hardening accelerator may be at least one selected from 2-ethyl-4methylimidazole, 1-(2-cyanoethyl)-2-alkylimidazole, 2-phenylimidazole, dimethylaminopyridine (DMAP), 3,3′-thiodipropionic acid, and 4,4′-thiodiphenol.

The hardening accelerator may be contained in an amount of 0.1 to 1 part by weight based on 100 parts by weight of the epoxy resin composite.

The filler may be an inorganic filler, and may be contained in an amount of 40 to 85 parts by weight based on 100 parts by weight of the epoxy resin composite.

The inorganic filler may be at least one selected from barium titanium oxide, barium strontium titanate, titanium oxide, lead zirconium titanate, lead lanthanum zirconate titanate, lead magnesium niobate-lead titanate, silver, nickel, nickel-coated polymer sphere, gold-coated polymer sphere, tin solder, graphite, tantalum nitride, metal silicon nitride, carbon black, silica, clay, aluminum, and aluminum borate.

The inorganic filler may be surface-treated with a silane coupling agent.

The viscosity enhancer may be contained in an amount of 1 to 5 parts by weight based on 100 parts by weight of the low-loss insulating resin composition.

The viscosity enhancer may be at least one of an organic viscosity enhancer and an inorganic viscosity enhancer.

The resin composition may further include a surface improving agent.

An insulating film may include the low-loss insulating resin composition.

The insulating film may be a mold film having a thickness of 200 μm or more.

A product may include the insulating film.

The product may be at least one of a substrate and an antenna package for a high frequency antenna module.

The low-loss insulating resin may be cast on the insulating film.

The filler may be an inorganic filler.

Other features and aspects will be apparent from the following detailed description, the drawings, and the claims.

### BRIEF DESCRIPTION OF DRAWINGS

FIG. 1 is a schematic view illustrating an example of a package including a low-loss insulating resin composition, wherein an insulating film is provided in an “A” portion.

Throughout the drawings and the detailed description, the same reference numerals refer to the same elements. The drawings may not be to scale, and the relative size, proportions, and depiction of elements in the drawings may be exaggerated for clarity, illustration, and convenience.

### DETAILED DESCRIPTION

The following detailed description is provided to assist the reader in gaining a comprehensive understanding of the methods, apparatuses, and/or systems described herein. However, various changes, modifications, and equivalents of the methods, apparatuses, and/or systems described herein will be apparent after an understanding of the disclosure of this application. For example, the sequences of operations described herein are merely examples, and are not limited to those set forth herein, but may be changed as will be apparent after an understanding of the disclosure of this application, with the exception of operations necessarily occurring in a certain order. Also, descriptions of features that are known in the art may be omitted for increased clarity and conciseness.

The features described herein may be embodied in different forms, and are not to be construed as being limited to the examples described herein. Rather, the examples described herein have been provided merely to illustrate some of the many possible ways of implementing the methods, apparatuses, and/or systems described herein that will be apparent after an understanding of the disclosure of this application.

Throughout the specification, when an element, such as a layer, region, or substrate, is described as being “on,” “connected to,” or “coupled to” another element, it may be directly “on,” “connected to,” or “coupled to” the other element, or there may be one or more other elements intervening therebetween. In contrast, when an element is described as being “directly on,” “directly connected to,” or “directly coupled to” another element, there can be no other elements intervening therebetween.

As used herein, the term “and/or” includes any one and any combination of any two or more of the associated listed items.

Although terms such as “first,” “second,” and “third” may be used herein to describe various members, components, regions, layers, or sections, these members, components, regions, layers, or sections are not to be limited by these terms. Rather, these terms are only used to distinguish one member, component, region, layer, or section from another member, component, region, layer, or section. Thus, a first member, component, region, layer, or section referred to in examples described herein may also be referred to as a second member, component, region, layer, or section without departing from the teachings of the examples.

Spatially relative terms such as “above,” “upper,” “below,” and “lower” may be used herein for ease of description to describe one element's relationship to another element as shown in the FIGURES. Such spatially relative terms are intended to encompass different orientations of the device in use or operation in addition to the orientation depicted in the FIGURES. For example, if the device in the FIGURES is turned over, an element described as being “above” or “upper” relative to another element will then be “below” or “lower” relative to the other element. Thus, the term “above” encompasses both the above and below orientations depending on the spatial orientation of the device. The device may also be oriented in other ways (for example, rotated 90 degrees or at other orientations), and the spatially relative terms used herein are to be interpreted accordingly.

The terminology used herein is for describing various examples only, and is not to be used to limit the disclosure. The articles “a,” “an,” and “the” are intended to include the plural forms as well, unless the context clearly indicates otherwise. The terms “comprises,” “includes,” and “has” specify the presence of stated features, numbers, operations, members, elements, and/or combinations thereof, but do not preclude the presence or addition of one or more other features, numbers, operations, members, elements, and/or combinations thereof.

Due to manufacturing techniques and/or tolerances, variations of the shapes shown in the drawings may occur. Thus, the examples described herein are not limited to the specific shapes shown in the drawings, but include changes in shape that occur during manufacturing.

Throughout the description of the present disclosure, when describing a certain technology is determined to evade the point of the present disclosure, the pertinent detailed description will be omitted.

In the following description, well-known functions or constructions are not described in detail since they would obscure the invention in unnecessary detail.

The features of the examples described herein may be combined in various ways as will be apparent after an understanding of the disclosure of this application. Further, although the examples described herein have a variety of configurations, other configurations are possible as will be apparent after an understanding of the disclosure of this application.

A. Insulating Resin Composition

A low-loss insulating resin composition according to an example may include (a) an epoxy resin composite including 40 to 60 parts by weight of a cyanate ester resin, 15 to 35 parts by weight of a biphenylaralkyl novolac resin, and 15 to 35 parts by weight of a fluorine-containing epoxy resin; (b) a hardener; (c) a thermoplastic resin; (d) a hardening accelerator; (e) an inorganic filler; (f) a viscosity enhancer; and (g) an additive.

(a) Epoxy Resin Composite

Cyanate Ester Resin

The cyanate ester resin in the epoxy resin composite may be contained in, but not limited to, an amount of 40 to 60 parts by weight based on the total weight of the epoxy resin composite. When the amount of the cyanate ester is less than 40 parts by weight, reactivity and curability may be insufficient. On the other hand, when the amount of the cyanate ester exceeds 60 parts by weight, the reaction control becomes difficult and the hardening may be accelerated or the moldability may be deteriorated. The cyanate ester resin may include, but is not limited to, a dicyclopentadienyl-bisphenol group or a tetramethylbiphenyl group.

Biphenylaralkyl Novolac Resin

The epoxy resin composite may include a biphenylaralkyl novolac resin in order to provide a cured product having high heat resistance. The biphenylaralkyl novolac resin may have excellent physical properties and crystallinity due to the biphenyl having a symmetrical structure and particularly, having many excellent physical properties such as low melt viscosity, low stress and high adhesion. The amount of the biphenylaralkyl novolac resin in the epoxy resin composite is not limited thereto, but may be 15 to 35 parts by weight based on the total weight of the epoxy resin composite. When the amount of the biphenylaralkyl novolac resin is less than 15 parts by weight, it is difficult to impart adequate heat resistance in the insulating film. On the other hand, when the amount exceeds 35 parts by weight, the curability may be deteriorated.

Fluorine-Containing Epoxy Resin

An amount of the fluorine-containing epoxy resin in the epoxy resin composite is not limited thereto, but may be 15 to 35 parts by weight based on the total weight of the epoxy resin composite.

When the amount of the fluorine-containing epoxy resin is less than 15 parts by weight, specific properties, such as heat resistance, high temperature and high humidity resistance, and chemical resistance, of the fluorine-containing epoxy resin may not be sufficient. On the other hand, when the amount exceeds 35 parts by weight, coagulation may occur due to the difference in polarity associated with the difference in electronegativity of the resin composition and the production cost may increase due to an increase in the use of the expensive fluorine-containing epoxy resin. The fluorine-containing epoxy resin is not limited thereto, but may be powder of at least one selected from polytetrafluoroethylene (PTFE), perfluoroalkoxy polymer (PFA), fluorinated ethylene-propylene copolymer (FEP), chlorotrifluoroethylene (CTFE), tetrafluoroethylene/chlorotrifluoroethylene copolymer (TFE/CTFE), ethylene-chlorotrifluoroethylene copolymer (ECTFE), ethylene-tetrafluoroethylene copolymer (ETFE), and polychlorotrifluoroethylene (PCTFE).

Among the above fluorine-containing epoxy resins, powder of the polytetrafluoroethylene (PTFE) resin having an extremely low dielectric constant and dielectric loss coefficient and a high glass transition temperature (Tg) may be used to ensure dielectric properties and minimize the deterioration of the physical properties of the composition due to the addition of the powder of the fluorine-containing epoxy resin.

(b) Hardener

The hardener contained in the insulating resin composition of examples disclosed herein may be an active ester in order to improve the low dissipation factor characteristics. The active ester hardener may be, but are not limited to, a compound having two or more high reactive ester groups such as phenol esters, thiophenol esters, N-hydroxyamine esters, esters of heterocyclic hydroxy compounds and the like. Although not limited thereto, the active ester hardener may include a dicyclopentadienyldiphenol structure. The hardener is not limited thereto, but may be mixed in an equivalent ratio of 0.5 to 1.5 to the mixed equivalent of the epoxy resin composite, and preferably an equivalent ratio of 1.0. When the equivalent ratio of the hardener is less than 0.5, low dissipation factor characteristics and flame retardancy of the insulating resin composition may be deteriorated. On the other hand, when the equivalent ratio is more than 1.5, adhesion and storage stability may be deteriorated.

(c) Thermoplastic Resin

The thermoplastic resin included in the insulating resin composition of this disclosure is not limited thereto, but may be added in an amount of 1 to 20 parts by weight based on the combined amount of the epoxy resin to improve elongation and adhesion to wiring materials.

The thermoplastic resin is not limited thereto, but may be at least one selected from polyvinyl acetal resin, phenoxy resin, polyimide resin, polyamideimide resin, polyetherimide resin, polysulfone resin, polyethersulfone resin, polyphenylene ether resin, polycarbonate resin, polyetheretherketone resin, polyester resin, phenolic resin, fluorine-based thermoplastic resin and polyacetal resin.

When a polyvinyl acetal resin is used as the thermoplastic resin of this disclosure, a functional group capable of forming a chelate bond with copper (Cu) may be partially contained in the polyvinyl acetal resin. The functional group which forms a chelate bond with copper (Cu) may be a carboxyl group, a carbonyl group, and an ether group, and preferably a carboxyl group.

(d) Hardening Accelerator

The hardening accelerator included in the insulating resin composition of this disclosure may be, but not limited to, imidazole or dimethylaminophenyl. Examples of the hardening accelerator may include 2-ethyl-4 methyl imidazole, 1-(2-cyanoethyl)-2-alkyl imidazole, 2-phenyl imidazole, DMAP, 3,3′-thiodipropionic acid, 4,4′-thiodiphenol and a mixture thereof. The hardening accelerator is not limited thereto, but may be included in an amount of 0.1 to 1 part by weight, more preferably 0.25 parts by weight, based on the total weight of the epoxy resin composite. When the amount of the hardening accelerator is less than 0.1 parts by weight, the hardening rate may be remarkably lowered. On the other hand, when the amount exceeds 1 part by weight, hardening may occur rapidly and it may be thereby difficult to obtain desired physical properties.

(e) Filler

The inorganic filler included in the resin composition of this disclosure may be, but not limited to, at least one selected from barium titanium oxide, barium strontium titanate, titanium oxide, lead zirconium titanate, lead lanthanum zirconate titanate, lead magnesium niobate-lead titanate, silver, nickel, nickel-coated polymer sphere, gold-coated polymer sphere, tin solder, graphite, tantalum nitride, metal silicon nitride, carbon black, silica, clay, aluminum, and aluminum borate.

The inorganic filler may be included in an amount of 40 to 85 parts by weight, and preferably 65 to 80 parts by weight, based on 100 parts by weight of the epoxy resin composite, in order to lower the expansion rate of the low-loss insulating resin composition. When the amount of the inorganic filler is less than 40 parts by weight, there is a problem that the coefficient of thermal expansion is increased. On the other hand, when the amount of the inorganic filler exceeds 85 parts by weight, it may be difficult to apply to a substrate processing such as lamination.

The organic filler may be, but is not necessarily limited to, Teflon-based products.

In addition, the inorganic filler may be surface-treated with a silane coupling agent, and it may be more preferable to include fillers of different sizes and shapes. Although not limited thereto, as the silane coupling agent, various kinds of amino-based, epoxy-based, acrylic-based, vinyl-based, and similar components may be used.

(f) Viscosity Enhancer

The insulating film may include a viscosity enhancer to form a high viscosity insulating composition. The viscosity enhancer may be, but is not limited to, inorganic and/or organic viscosity enhancers. The viscosity-enhancer may be contained in an amount of 1 to 10 parts by weight, more preferably 1 to 3 parts by weight, based on 100 parts by weight of the low-loss insulating resin composition.

The organic viscosity enhancer may be at least an organic viscosity enhancer one selected from urea-modified polyamide waxes, thixotropic resins, cellulose ethers, starches, natural hydrocolloids, synthetic biopolymers, polyacrylates, alkali-activated acrylic acid emulsions, fatty acid alkanamides, but is not limited thereto.

Although not limited thereto, the inorganic viscosity enhancer may be at least one selected from magnesium oxide, magnesium hydroxide, amorphous silica and layered silicate.

Although not limited thereto, the viscosity enhancer may be selected from inorganic viscosity enhancers such as silica. The silica may effectively prevent precipitation without impairing the properties of the resin composition.

(g) Additives

In this disclosure, another hardener, another hardening accelerator, a leveling agent, a flame retardant, and the like may be further included, if necessary, in addition to the compositions listed above, as long as the desired properties of this disclosure are not impaired. Although not limited thereto, the insulating resin composition of this disclosure may further include at least one additive such as a surface-improving agent, a defoaming agent, a thermoplastic resin, a filler, a softener, a plasticizer, an antioxidant, a flame retardant, a flame retardant aid, a lubricant, an antistatic agent, a colorant, a heat stabilizer, a light stabilizer, a UV absorber, a coupling agent or an anti-settling agent.

Although not limited thereto, the insulating resin composition of this disclosure may use different solvents having different boiling points for the coating and filming of the insulating resin composition and include an additive such as a surface tension controlling agent, a defoaming agent, a thermoplastic resin, and the like.

B. Insulating Film

An insulating film which has improved hygroscopic property, reliability, thermal stability and mechanical properties may be produced with the resin composition of the disclosed examples.

The insulating film may be applied to a buildup layer of a printed circuit board 110, a mold layer of a PLP, and a back side redistribution layer (RDL).

The insulating film may be a mold film having a thickness of 200 μm or more. In this case, a film having a thickness of 200 μm or more can be easily produced by using the insulating resin composition of this disclosure and adding a surface improving agent and a viscosity enhancer.

The insulating film may be a mold film having a Cu adhesion of 0.5 kgf/cm or more.

According to this disclosure, the low-loss insulating resin composition which provides package stability and high reliability, and forms a thick film can be provided.

Accordingly, it is possible to form an insulating film with a very high thickness, compared to a typical insulating material, using the low-loss insulating resin composition of this disclosure.

Further, it is also possible to provide a substrate and an antenna package which has excellent reliability based on the low-loss insulating resin composition of this disclosure.

Hereinafter, although more detailed descriptions will be given by examples, those are only for explanation and does not limit the disclosure. In the following examples, only examples implementing specific compounds are exemplified. However, it is apparent to those skilled in the art that equivalents of similar compounds can be exhibited even when these equivalents are used.

### Example

Preparation of Low-Loss Insulating Resin Composition

Insulating resin compositions of Example 1 and Comparative Examples 1 to 3 including an epoxy resin composite including a cyanate ester resin, a biphenylaralkyl novolac resin, and a fluorine-containing epoxy resin; an active ester-based hardener; a hardening accelerator; an inorganic filler; an organic/inorganic viscosity enhancer; an initiating agent; and an additive as in the composition shown in the following Table 1 were prepared.

More particularly, the hardener was added in an amount of 1.0 equivalent based on the epoxy resin composite, and spherical amino-treated silica slurry having a size distribution of 500 nm to 5 μm was added and stirred at 300 rpm for 3 hours.

A hardening accelerator of dimethylaminopyridine (DMAP), a surface improving additive and a viscosity enhancer were added to the mixture and further mixed for 1 hour to provide a low-loss insulating resin composition. The composition of the insulating resin composition of Example 1 and Comparative Examples 1 to 3 is shown in detail in Table 1.

TABLE 1

| | | | Comparative | Comparative | Comparative |
|---|---|---|---|---|---|
| Component | | Example 1 | Example 1 | Example 2 | Example 3 |
| Epoxy resin | Cyanate ester | 50.0% | 50.0% | 50.0% | 70.0% |
| | Biphenyl aralkyl novolac | 25.0% | 50.0% | — | 15.0% |
| | type epoxy | | | | |
| | Fluorine-containing epoxy | 25.0% | — | 50.0% | 15.0% |
| Hardener | Active ester | 1.0 based on | 1.0 based on | 1.0 based on | 1.0 based on |
| | | the total | the total | the total | the total |
| | | epoxy resin | epoxy resin | epoxy resin | epoxy resin |
| thermoplastic | Phenolic resin/ | 10phr based | 10phr based | 10phr based | 10phr based |
| resin | Fluorothermoplastic resin | on the total | on the total | on the total | on the total |
| | | (epoxy resin + | (epoxy resin + | (epoxy resin + | (epoxy resin + |
| | | hardener) | hardener) | hardener) | hardener) |
| Hardening | DMAP | 0.25phr | 0.25phr | 0.25phr | 0.25phr |
| accelerator | (Dimethylaminopyridine) | based on the | based on the | based on the | based on the |
| | | total hardener | total hardener | total hardener | total hardener |
| Inorganic | SiO₂ | 75% based | 75% based | 75% based | 75% based |
| filler | | on the total | on the total | on the total | on the total |
| | | (epoxy + | (epoxy + | (epoxy + | (epoxy + |
| | | hardener) | hardener) | hardener) | hardener) |
| Viscosity | Inorganic/organic viscosity | 1-3% based | 1-3% based | 1-3% based | 1-3% based |
| enhancer | enhancer | on the total | on the total | on the total | on the total |
| | | mixed | mixed | mixed | mixed |
| | | solution | solution | solution | solution |
| Additive | BYK-337 | 0.5 phr | 0.5 phr | 0.5 phr | 0.5 phr |

### Preparation of Insulation Films and Evaluation of Mechanical Properties

The prepared high-viscosity low-loss insulating resin composition may be cast on a polyethylene terephthalate film (PET film) to a thickness of more than 200 μm to provide a roll-shaped film product, which was used as a film-type molding material.

The evaluation results of the mechanical properties of the film prepared from the composition of the epoxy resin of Example 1 and Comparative Examples 1 to 3 are shown in Table 2 below.

TABLE 2

| | Exam- | Comparative | Comparative | Comparative |
|---|---|---|---|---|
| | ple 1 | Example 1 | Example 2 | Example 3 |
| Cyanate ester-type | 50 | 50 | 50 | 70 |
| epoxy | | | | |
| Biphenylaralkyl | 25 | 50 | | 15 |
| novolac type epoxy | | | | |
| Fluorine-containing | 25 | | 50 | 15 |
| epoxy | | | | |

Physical properties

| | | | | |
|---|---|---|---|---|
| Chemical copper | >0.5 | 0.46 | 0.48 | <0.4 |
| adhesion (kgf/cm) | | | | |
| Moisture content | <0.3 | — | 0.37 | — |
| (wt. %) | | | | |
| CTE (ppm/° C.) | <15 | 18 | — | 16 |
| Df | <0.003 | 0.0038 | 0.0034 | 0.0025 |

In the evaluation of mechanical properties of molding materials, it was confirmed that the dissipation factor (Df) of the molding material of Example 1 was less than 0.003 tangent δ, the coefficient of thermal expansion was less than 15 ppm/° C., the moisture content was less than 0.3 wt %, and adhesion to Cu was more than 0.5 kgf/cm.

As shown in Table 2, it was also confirmed that the insulating resin composition of Example, 1 in which three kinds of epoxy resins were mixed, has a superior dissipation factor (Df), coefficient of thermal expansion, moisture content, and adhesion to Cu to the insulating resin compositions of Comparative Examples 1 to 3.

When it was used as a molding material for a package, the package satisfied all of the Highly Accelerated Stress Test (HAST) and Thermal Cycle (TC) reliability standards as a result of the reliability evaluation of the package.

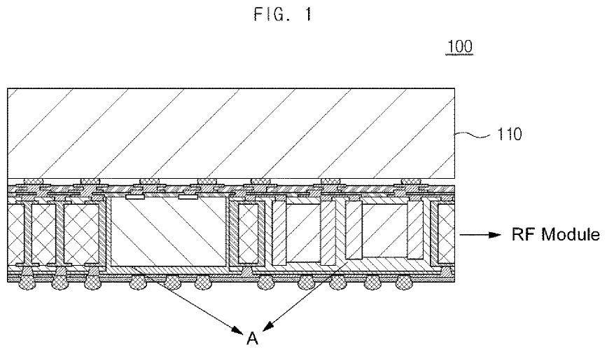

Thus, the insulation film may be used as a low-loss molding material in an antenna Printed Circuit Board (PCB) 110 as shown in FIG. 1.

The prepared antenna package may reduce signal loss and improve the blister of the back-side redistribution layer (RDL) after and reflow.

By using the low-loss insulating resin composition of this disclosure, it is possible to manufacture a thick film having a thickness of 200 μm or more because of easy thickness control during film casting, so that it is applicable to packaging from small to large area products.

On the other hand, when a typical molding material of granular or liquid type is used, an expensive compression molding equipment may be needed, and since the molding and hardening are carried out with one equipment, a long processing time may be needed. However, by using the film-type molding material prepared by the low-loss insulating resin composition of this disclosure, relatively inexpensive lamination equipment can be used and the hardening can be separately performed in a convection oven after molding, which may shorten the processing time and improve the productivity of the final product.

The film using the low-loss dielectric resin composition of this disclosure has a low dielectric dissipation factor of less than 0.003 tangent (δ), a low thermal expansion coefficient of less than 15 ppm/° C., a low moisture content of less than 0.3 wt. %, high adhesion to Cu of more than 0.5 kgf/cm after hardening.

The product of the above examples may be a substrate or an antenna package for a high frequency antenna module.

The low-loss insulating resin composition may have excellent reliability and adhesion, low dissipation factor characteristics, and improved thermal and mechanical properties due to its low hygroscopic property.

It may be possible to provide an insulating film having a thick thickness that can secure the stability and reliability of a printed circuit board or a packaged product using the low-loss insulating resin composition.

Thickness control during film casting may be easy, insulating films having thick thickness of 200 μm or more may be manufactured, and packaging may be available from small size to large size products.

It may be possible to provide a substrate for a high frequency antenna module and an antenna package using the insulating film to ensure excellent processability and reliability, low dissipation factor characteristics, and reduced signal loss.

It may be possible to use relatively inexpensive equipment using the insulating film, shorten the process time, and effectively increase the productivity of the substrate and the package.

While this disclosure includes specific examples, it will be apparent after an understanding of the disclosure of this application that various changes in form and details may be made in these examples without departing from the spirit and scope of the claims and theft equivalents. The examples described herein are to be considered in a descriptive sense only, and not for purposes of limitation. Descriptions of features or aspects in each example are to be considered as being applicable to similar features or aspects in other examples. Suitable results may be achieved if the described techniques are performed in a different order, and/or if components in a described system, architecture, device, or circuit are combined in a different manner, and/or replaced or supplemented by other components or their equivalents. Therefore, the scope of the disclosure is defined not by the detailed description, but by the claims and their equivalents, and all variations within the scope of the claims and their equivalents are to be construed as being included in the disclosure.

What is claimed is:

1. A low-loss insulating resin composition comprising:
an epoxy resin composite comprising a cyanate ester resin, a biphenylaralkyl novolac resin, and a fluorine-containing epoxy resin;
an active ester hardener;
a thermoplastic resin;
a hardening accelerator;
a filler; and
a viscosity enhancer.

2. The resin composition of claim 1, wherein the epoxy resin composite comprises 40 to 60 parts by weight of the cyanate ester resin, 15 to 35 parts by weight of the biphenylaralkyl novolac epoxy resin, and 15 to 35 parts by weight of the fluorine-containing epoxy resin.

3. The resin composition of claim 1, wherein the hardener is contained in an amount of 0.5 to 1.5 equivalents based on a mixed equivalent of the epoxy resin composite.

4. The resin composition of claim 1, wherein the thermoplastic resin is contained in an amount of 5 to 15 parts by weight based on 100 parts by weight of the epoxy resin composite and the active ester hardener.

5. The resin composition of claim 1, wherein the thermoplastic resin is at least one of a polyvinyl acetal resin, a phenoxy resin, a polyimide resin, a polyamideimide resin, a polyetherimide resin, a polysulfone resin, a polyethersulfone resin, a polyphenylene ether resin, a polycarbonate resin, a polyetheretherketone resin, a polyester resin, a phenolic resin, a fluorine-based thermoplastic resin, and a polyacetal resin.

6. The resin composition of claim 1, wherein the hardening accelerator is at least one of 2-ethyl-4methylimidazole, 1-(2-cyanoethyl)-2-alkylimidazole, 2-phenylimidazole, dimethylaminopyridine (DMAP), 3,3′-thiodipropionic acid, and 4,4′-thiodiphenol.

7. The resin composition of claim 1, wherein the hardening accelerator is contained in an amount of 0.1 to 1 part by weight based on 100 parts by weight of the epoxy resin composite.

8. The resin composition of claim 1, wherein the filler is an inorganic filler, and is contained in an amount of 40 to 85 parts by weight based on 100 parts by weight of the epoxy resin composite.

9. The resin composition of claim 8, wherein the inorganic filler is at least one of barium titanium oxide, barium strontium titanate, titanium oxide, lead zirconium titanate, lead lanthanum zirconate titanate, lead magnesium niobate-lead titanate, silver, nickel, nickel-coated polymer sphere, gold-coated polymer sphere, tin solder, graphite, tantalum nitride, metal silicon nitride, carbon black, silica, clay, aluminum, and aluminum borate.

10. The resin composition of claim 8, wherein the inorganic filler is surface-treated with a silane coupling agent.

11. The resin composition of claim 1, wherein the viscosity enhancer is contained in an amount of 1 to 5 parts by weight based on 100 parts by weight of the low-loss insulating resin composition.

12. The resin composition of claim 1, wherein the viscosity enhancer is at least one of an organic viscosity enhancer and an inorganic viscosity enhancer.

13. The resin composition of claim 1, further comprising a surface improving agent.

14. An insulating film comprising the low-loss insulating resin composition of claim 1.

15. The insulating film of claim 14, wherein the insulating film is a mold film having a thickness of 200 μm or more.

16. A product comprising the insulating film of claim 14.

17. The product of claim 16, wherein the product is at least one of a substrate and an antenna package for a high frequency antenna module.

18. The insulating film of claim 14, wherein the low-loss insulating resin is cast on the insulating film.

19. The resin composition of claim 1, wherein the filler is an inorganic filler.
